(19) United States
(12) Patent Application Publication
(10) Pub. No.: US 2016/0218695 A1
(43) Pub. Date: Jul. 28, 2016

(54) LADDER FILTER

(71) Applicant: Murata Manufacturing Co., Ltd., Nagaokakyo-shi (JP)

(72) Inventor: Koji NOSAKA, Nagaokakyo-shi (JP)

(21) Appl. No.: 15/002,527

(22) Filed: Jan. 21, 2016

(30) Foreign Application Priority Data
Jan. 23, 2015 (JP) 2015-011611

(51) Int. Cl. H03H 9/64

(52) U.S. Cl. CPC H03H 9/568; H03H 9/64

(57) ABSTRACT

A ladder filter includes a series arm resonator arranged on a series arm connecting an input terminal and an output terminal to each other, and at least one parallel arm resonator. The series arm resonator and the at least one parallel arm resonator are resonators each including a resonant point and an anti-resonant point. The series arm resonator includes first and second series arm resonators connected in parallel with each other. For a resonant frequency fr1 and an anti-resonant frequency fa1 of the first series arm resonator, and for a resonant frequency fr2 and an anti-resonant frequency fa2 of the second series arm resonator, resonant frequency difference Δfr=|fr1−fr2|>|fa2−fr1|.

### BACKGROUND OF THE INVENTION

1. Field of the Invention

The present invention relates to a ladder filter including a series arm resonator and a parallel arm resonator.

2. Description of the Related Art

Hitherto, a ladder filter including a plurality of surface acoustic wave resonators has been widely used in, for example, the RF stage of a cellular phone. Japanese Unexamined Patent Application Publication No. 2000-77972 discloses an example of such a ladder filter. In Japanese Unexamined Patent Application Publication No. 2000-77972, a plurality of surface acoustic wave resonators having different resonant frequencies are connected in parallel with one another on a series arm. Further, on a parallel arm, a plurality of surface acoustic wave resonators having different resonant frequencies are connected in series with one another. It is stated in Japanese Unexamined Patent Application Publication No. 2000-77972 that, in the ladder filter disclosed therein, by employing the configuration described above, the pass band width can be adjusted so as to be increased, and steepness near the pass band can be enhanced.

In the ladder filter disclosed in Japanese Unexamined Patent Application Publication No. 2000-77972, although the steepness of the filter characteristics is enhanced, the steepness is enhanced through adjustment for increasing the pass band.

In recent years, various narrow communication frequency bands have come to be used. Further, intervals between neighboring communication frequency bands have become narrow. The ladder filter disclosed in Japanese Unexamined Patent Application Publication No. 2000-77972 may not support these situations.

### SUMMARY OF THE INVENTION

Accordingly, preferred embodiments of the present invention provide a ladder filter that allows a band width to be reduced and allows the steepness of filter characteristics to be enhanced.

A ladder filter according to a broad aspect of various preferred embodiments of the present invention includes an input terminal; an output terminal; at least one series arm resonator arranged on a series arm connecting the input terminal and the output terminal to each other; and at least one parallel arm resonator provided on a parallel arm connected between the series arm and a ground potential. The at least one series arm resonator and the at least one parallel arm resonator are resonators each including a resonant point and an anti-resonant point. The at least one series arm resonator includes a first series arm resonator and a second series arm resonator connected in parallel with each other. For a resonant frequency fr1 and an anti-resonant frequency fa1 of the first series arm resonator, and for a resonant frequency fr2 and an anti-resonant frequency fa2 of the second series arm resonator, a relation is satisfied when fr1>fr2 and fa1 >fa2, the relation being a resonant frequency difference Δfr=|fr1−fr2|>|fa2−fr1|.

Preferably, the resonant frequency fr1 of the first series arm resonator and the anti-resonant frequency fa2 of the second series arm resonator are located within a pass band. In this case, a loss in the pass band is sufficiently reduced.

Preferably, the at least one parallel arm resonator includes a first parallel arm resonator defining a pass band. In this case, an attenuation pole in a frequency range below the pass band is provided by the resonant point of the first parallel arm resonator.

Preferably, the at least one parallel arm resonator includes a second parallel arm resonator that has the same or substantially the same resonant frequency and the same or substantially the same anti-resonant frequency as the resonant frequency and the anti-resonant frequency of the first series arm resonator respectively. In this case, a peak appearing in a frequency range below the pass band is suppressed in the filter characteristics.

Preferably, a third series arm resonator is connected in parallel with the first series arm resonator and the second series arm resonator. In this way, the third series arm resonator may be further connected in parallel.

Preferably, a fourth series arm resonator is provided on the series arm in series with the first and second series arm resonators. As a result of connection of the fourth series arm resonator, out-of-band attenuation is sufficiently increased.

A ladder filter according to another aspect of various preferred embodiments of the present invention includes an input terminal; an output terminal; at least one series arm resonator arranged on a series arm connecting the input terminal and the output terminal to each other; and at least one parallel arm resonator provided on a parallel arm connected between the series arm and a ground potential. The at least one series arm resonator and the at least one parallel arm resonator are resonators each including a resonant point and an anti-resonant point. The at least one parallel arm resonator includes a third parallel arm resonator and a fourth parallel arm resonator connected in series with each other on the parallel arm. For a resonant frequency fr3 and an anti-resonant frequency fa3 of the third parallel arm resonator and for a resonant frequency fr4 and an anti-resonant frequency fa4 of the fourth parallel arm resonator, a relation is satisfied when fr3<fr4 and fa3<fa4, the relation being a resonant frequency difference Δfr=|fr3−fr4|>|fr4−fa3|.

Preferably, the anti-resonant frequency fa3 of the third parallel arm resonator and the resonant frequency fr4 of the fourth parallel arm resonator are located within a pass band. In this case, the loss in the pass band is sufficiently reduced.

Preferably, the at least one series arm resonator includes a fifth series arm resonator defining the pass band. In this case, an attenuation pole in a frequency range above the pass band is provided by the anti-resonant frequency of the fifth series arm resonator.

Preferably, the at least one series arm resonator includes a sixth series arm resonator that has the same or substantially the same resonant frequency and the same or substantially the same anti-resonant frequency as the resonant frequency and the anti-resonant frequency of the third parallel arm resonator respectively. In this case, a peak appearing in a frequency range above the pass band in the filter characteristics is efficiently suppressed. As a result, attenuation in an attenuation range within the frequency range above the pass band is increased.

Preferably, a fifth parallel arm resonator is connected in series with the third parallel arm resonator and the fourth parallel arm resonator. In this way, the fifth parallel arm resonator may be further connected in series, such that the steepness of the filter characteristics is adjusted.

Preferably, a different parallel arm different from the parallel arm on which the third and fourth parallel arm resonators are provided is provided, and a sixth parallel arm resonator is provided on the different parallel arm. By providing the sixth parallel arm resonator on the different parallel arm, out-of-band attenuation is increased.

Preferably, in the above aspects and preferred embodiments of the present invention, respective fractional band widths of all the resonators are the same or substantially the same. In this case, the attenuation characteristics are enhanced in the vicinity of the band width of the resonator.

Preferably, all the resonators are provided on the same piezoelectric substrate. In this case, the manufacturing process is simplified and the size of the ladder filter is reduced.

Preferably, the at least one series arm resonator and the at least one parallel arm resonator are each made of a surface acoustic wave resonator. In this case, the steepness of the filter characteristics is further effectively enhanced.

According to ladder filters of the first and second preferred embodiments of the present invention, the band width is reduced and the steepness of the filter characteristics is enhanced.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a ladder filter according to a first preferred embodiment of the present invention.

FIG. 2 is a circuit diagram illustrating a circuit in which a first series arm resonator and a second series arm resonator are connected in parallel with each other.

FIG. 3A is a diagram illustrating the impedance-frequency characteristics of the first and second series arm resonators illustrated in FIG. 2, and FIG. 3B is a diagram illustrating the impedance-frequency characteristics of a circuit defined by connecting the first series arm resonator and the second series arm resonator in parallel with each other.

FIG. 4 is a diagram illustrating the attenuation-frequency characteristics of the circuit illustrated in FIG. 2.

FIG. 5 is a circuit diagram of a ladder filter of a second preferred embodiment of the present invention.

FIG. 6A is a diagram illustrating the impedance-frequency characteristics of a first series arm resonator, a second series arm resonator, and a parallel arm resonator used in the second preferred embodiment of the present invention, and FIG. 6B is a diagram illustrating the impedance-frequency characteristics between the input and output terminals of the ladder filter of the second preferred embodiment of the present invention.

FIG. 7 is a diagram illustrating the attenuation-frequency characteristics of the ladder filter of the second preferred embodiment of the present invention.

FIG. 8 is a circuit diagram illustrating a circuit in which a third parallel arm resonator and a fourth parallel arm resonator are connected in series with each other on a parallel arm.

FIG. 9A illustrates the impedance-frequency characteristics of the third parallel arm resonator and the fourth parallel arm resonator, and FIG. 9B is a diagram illustrating the composite impedance-frequency characteristics of a circuit in which the third parallel arm resonator and the fourth parallel arm resonator are connected in series with each other.

FIG. 10 is a diagram illustrating the attenuation-frequency characteristics of the circuit illustrated in FIG. 8.

FIG. 11 is a circuit diagram of a ladder filter according to a third preferred embodiment of the present invention.

FIG. 12A is a diagram illustrating the impedance-frequency characteristics of third and fourth parallel arm resonators and the fifth series arm resonator used in the third preferred embodiment of the present invention, and FIG. 12B is a diagram illustrating the impedance-frequency characteristics between the input and output terminals of the ladder filter of the third preferred embodiment of the present invention.

FIG. 13 is a diagram illustrating the attenuation-frequency characteristics of the ladder filter of the third preferred embodiment of the present invention.

FIG. 14 is a diagram illustrating the attenuation-frequency characteristics of the ladder filter of the first preferred embodiment of the present invention.

FIG. 15 is a circuit diagram of a ladder filter according to a fourth preferred embodiment of the present invention.

FIG. 16 is a circuit diagram of a ladder filter according to a fifth preferred embodiment of the present invention.

FIG. 17 is a circuit diagram of a ladder filter according to a sixth preferred embodiment of the present invention.

FIG. 18 is a circuit diagram illustrating a duplexer as a seventh preferred embodiment of the present invention.

FIG. 19 is a circuit diagram illustrating a duplexer as an eighth preferred embodiment of the present invention.

FIG. 20 is a front sectional view illustrating an example of the structure of a surface acoustic wave resonator.

### DETAILED DESCRIPTION OF THE PREFERRED EMBODIMENTS

Hereinafter, the present invention will be clarified by describing specific preferred embodiments of the present invention.

Note that the preferred embodiments described in the present specification are illustrative and partial replacement or combination of portions of a configuration are possible among different preferred embodiments.

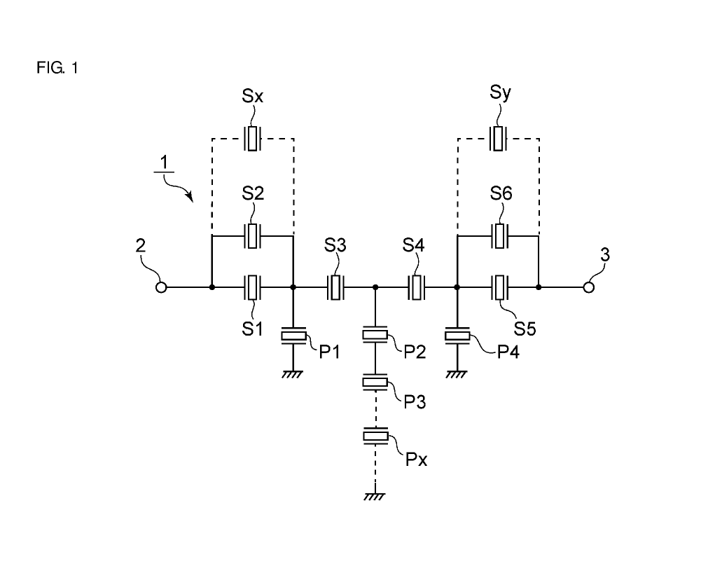

FIG. 1 is a circuit diagram of a ladder filter according to a first preferred embodiment of the present invention. A ladder filter 1 includes an input terminal 2 and an output terminal 3. Series arm resonators S1, S3, S4, and S5 are provided sequentially from the input terminal 2 side, on a series arm connecting the input terminal 2 and the output terminal 3 to each other. A series arm resonator S2 is connected in parallel with the series arm resonator S1. Similarly, a series arm resonator S6 is connected in parallel with the series arm resonator S5.

The series arm resonators S1 and S5 are first series arm resonators, and the series arm resonators S2 and S6 are second series arm resonators.

Note that in a portion in which the first series arm resonator S1 and the second series arm resonator S2 are connected in parallel, at least one third series arm resonator Sx may further be connected as illustrated by using a broken line. A third series arm resonator Sy may further be connected in parallel with the series arm resonators S5 and S6.

The series arm resonators S3 and S4 connected in series with a configuration in which the first and second series arm resonators S1 and S2 are connected in parallel are fourth series arm resonators.

A plurality of parallel arms connecting the series arm to the ground potential are provided. More specifically, a parallel arm resonator P1 is provided on a parallel arm connecting a connection node between the series arm resonator S1 and the series arm resonator S3 to the ground potential. Parallel arm resonators P2 and P3 are provided on a parallel arm connecting a connection node between the series arm resonators S3 and S4 to the ground potential. The parallel arm resonator P2 is a third parallel arm resonator, and the parallel arm resonator P3 is a fourth parallel arm resonator. The third parallel arm resonator P2 and the fourth parallel arm resonator P3 are connected in series with each other.

A parallel arm resonator P4 is connected between a connection node between the series arm resonator S4 and the series arm resonator S5 and the ground potential.

Note that in addition to the third parallel arm resonator P2 and the fourth parallel arm resonator P3, at least one fifth parallel arm resonator Px may further be connected in series, as illustrated by using a broken line.

The parallel arm resonators P1 and P4 are parallel arm resonators to provide the pass band of the ladder filter 1. In other words, the parallel arm resonators P1 and P4 together with the series arm resonators S1, S3, S4, and S5 define a pass band. The parallel arm resonators P1 and P4 are sixth parallel arm resonators.

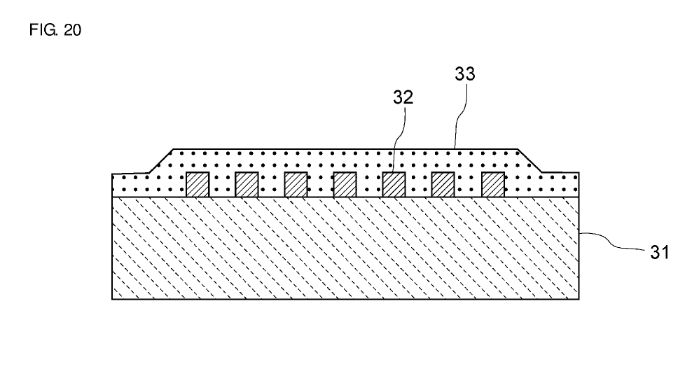

Each of the series arm resonators S1 to S6 and the parallel arm resonators P1 to P4 is a resonator including a resonant point and an anti-resonant point. In the present preferred embodiment, all the resonators preferably are surface acoustic wave resonators, for example. FIG. 20 illustrates an example of the structure of a surface acoustic wave resonator. This surface acoustic wave resonator has a structure in which an interdigital transducer (IDT) electrode 32 and a dielectric layer 33 are stacked on a piezoelectric substrate 31. However, the structure of the surface acoustic wave resonator is not specifically limited.

The first characteristic of the ladder filter 1 is that in the case where fr1>fr2 and fa1>fa2 for a resonant frequency fr1 and an anti-resonant frequency fa1 of the series arm resonators S1 and S5 as the first series arm resonators and for a resonant frequency fr2 and an anti-resonant frequency fa2 of the series arm resonators S2 and S6 as the second series arm resonators, the following relation is satisfied: a resonant frequency difference Δfr=|fr1−fr2|>|fa2−fr1|. As a result, the band width is reduced and the steepness of the filter characteristics is enhanced. In addition, electric power handling capability is enhanced.

The second characteristic of the ladder filter 1 is that in the case where fr3<fr4 and fa3<fa4 for a resonant frequency fr3 and an anti-resonant frequency fa3 of the parallel arm resonator P2 as the third parallel arm resonator and for a resonant frequency fr4 and an anti-resonant frequency fa4 of the parallel arm resonator P3 as the fourth parallel arm resonator, the following relation is satisfied: a resonant frequency difference Δfr=|fr3−fr4|>|fr4−fa3|. Also due to this, the band width is reduced and the steepness of the filter characteristics is enhanced, in the filter characteristics. In addition, the electric power handling capability is enhanced.

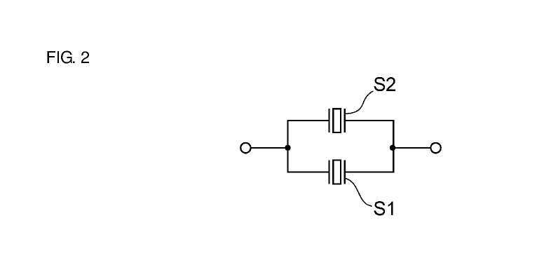

This will be described in more detail with reference to FIG. 2 to FIG. 14 below.

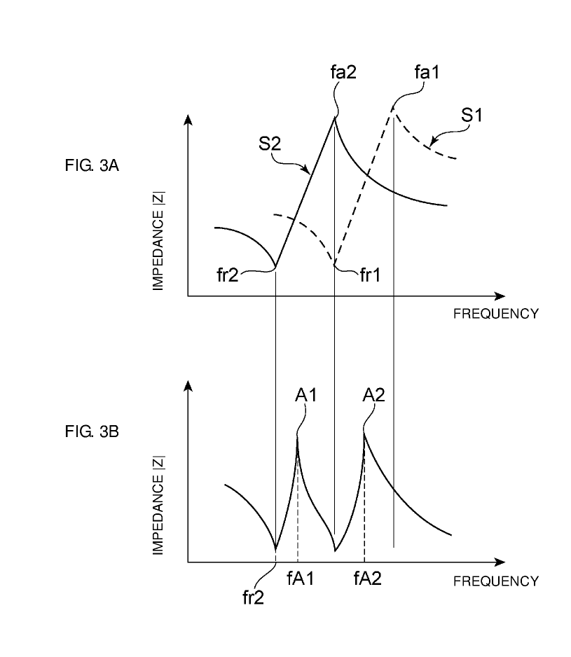

FIG. 2 illustrates a circuit in which the series arm resonator S1 as one of the first series arm resonators and the series arm resonator S2 as one of the second series arm resonators are connected in parallel with each other. The impedance frequency characteristics of the first series arm resonator S1 and the second series arm resonator S2 are illustrated in FIG. 3A. The first series arm resonator S1 is a series arm resonator to provide the original pass band of the ladder filter 1. Hence, the resonant frequency fr1 is located within the pass band.

On the other hand, the resonant frequency fr2 of the second series arm resonator S2 is located in a frequency range below the resonant frequency fr1. In the present preferred embodiment, the resonant frequency and the anti-resonant frequency of the series arm resonator S2 are a resonant frequency and an anti-resonant frequency similar to those of the parallel arm resonators P1 and P4 illustrated in FIG. 1. Hence, the resonant frequency fr2 is the same as the frequency of an attenuation pole provided in a frequency range below the pass band. Note that it is assumed that similar resonant frequencies or similar anti-resonant frequencies refer to not only the case of frequencies being the same but also the case of frequencies being within a frequency range smaller than the width of the pass band of a filter. With a difference in frequency to such an extent, similar impedance frequency characteristics are realized and the advantageous effects of the present invention are reliably obtained. Further, the respective impedance characteristics of the resonators are allowed to be slightly different from each other.

Note that the anti-resonant frequency fa2 is located within a pass band. Although not specifically limited, it is preferable that the anti-resonant frequency fa2 be the same or substantially the same as the resonant frequency fr1. This will allow a loss within the pass band to be sufficiently reduced.

FIG. 3B is a diagram illustrating the impedance-frequency characteristics of the circuit illustrated in FIG. 2. In the case where the first series arm resonator S1 and the second series arm resonator S2 are connected in parallel with each other, two peaks A1 and A2 appear in the frequency characteristics of the impedance, as illustrated in FIG. 3B. A frequency fA2 of the peak A2 is lower than the anti-resonant frequency fa1. On the other hand, a frequency fA1 of the peak Al is higher than the resonant frequency fr2.

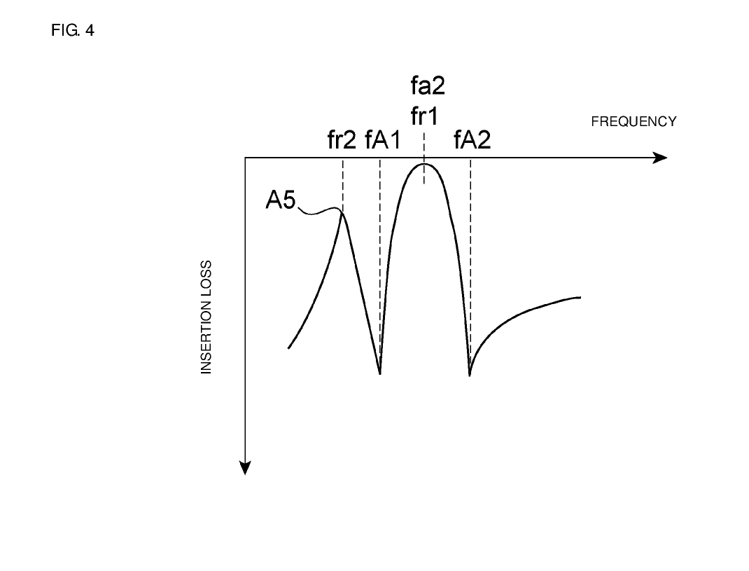

FIG. 4 is a diagram illustrating the attenuation-frequency characteristics of the circuit illustrated in FIG. 2. In the circuit illustrated in FIG. 2, lower-frequency and higher-frequency attenuation poles are located at the frequencies fA1 and fA2. Hence, compared with frequency characteristics in the case where only the first series arm resonator S1 is used and the second series arm resonator S2 is not used, both of the higher-frequency attenuation pole and the lower-frequency attenuation pole are shifted toward the center-frequency of the pass band. Hence, the band width is reduced. In addition, since the attenuation poles approach the center frequency, attenuation characteristics near the pass band are sufficiently enhanced. Since the resonant frequency fr1 of the first series arm resonator having a low impedance is combined in parallel with the anti-resonant frequency fa2 of the second series arm resonator S2 having a high impedance and low electric power handling capability, electric power handling capability is enhanced.

As described above, to make the higher-frequency attenuation pole and the lower-frequency attenuation pole be closer to the center frequency, it is necessary that a resonant frequency difference Δfr=|fr1−fr2|>|fa2−fr1| in the case where fr1>fr2 and fa1>fa2. In other words, it is necessary that the resonant frequency difference Δfr is larger than the absolute value of a difference between the anti-resonant frequency fa2 of the second series arm resonator S2 and the resonant frequency fr1 of the first series arm resonator S1.

This allows the frequencies of the peaks Al and A2 in FIG. 3B to approach the center frequency of the filter characteristics.

However, as illustrated in FIG. 4, a peak A5 with small attenuation appears in a frequency range below the pass band. This is due to the fact that the impedance becomes locally minimum at the position corresponding to the resonant frequency fr2 in FIG. 3B.

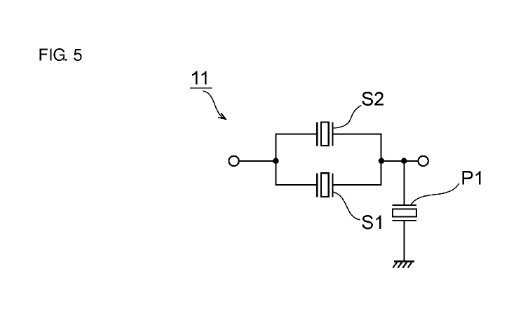

Hence, to realize favorable filter characteristics, it is preferable to suppress the peak A5 to increase the attenuation at the peak A5. FIG. 5 is a circuit diagram of a ladder filter, as a second preferred embodiment of the present invention, that suppresses such a peak. A ladder filter 11 includes the parallel arm resonator P1 in addition to the first series arm resonator S1 and the second series arm resonator S2 described above. The impedance-frequency characteristics of the parallel arm resonator P1 are the same as the impedance-frequency characteristics of the second series arm resonator S2. In other words, the parallel arm resonator P1 is a parallel arm resonator defining the pass band, and the anti-resonant frequency is within the pass band.

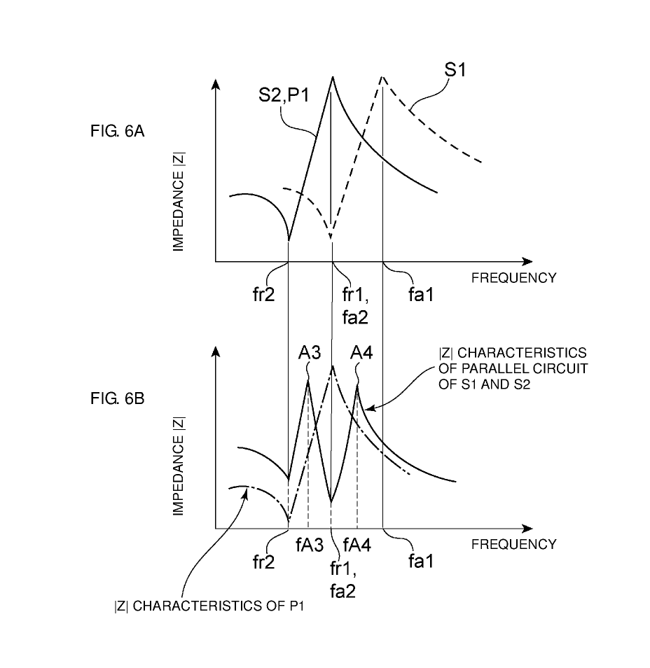

FIG. 6A illustrates the impedance-frequency characteristics of the first series arm resonator S1 and the second series arm resonator S2. The resonant frequency and the anti-resonant frequency of the parallel arm resonator P1 described above are respectively the same as the resonant frequency and the anti-resonant frequency of the second series arm resonator S2, as described above. The magnitude |Z| of the impedance of the second series arm resonator S2 may be different from that of the first series arm resonator S1.

FIG. 6B is a diagram illustrating the impedance-frequency characteristics in the ladder filter 11 of the second preferred embodiment.

Here, peaks A3 and A4 of the impedance appear. A frequency fA3 of the peak A3 is higher than the resonant frequency fr2 and lower than the anti-resonant frequency fa2. A frequency fA4 of the peak A4 is higher than the resonant frequency fr1 and lower than the anti-resonant frequency fa1.

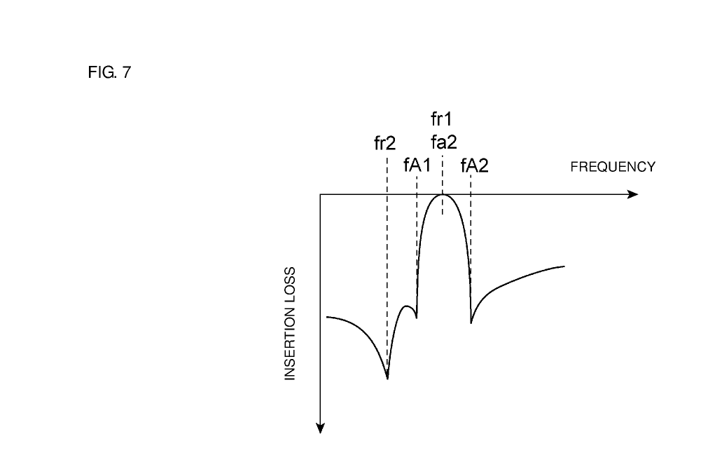

In the second preferred embodiment, the resonant point of the first parallel arm resonator P1 is located so as to be the same as the resonant frequency fr2 determined by the first series arm resonator S1 and the second series arm resonator S2. As a result, in the attenuation-frequency characteristics illustrated in FIG. 7, a peak in a frequency range below the pass band is suppressed. This is because a signal is passed to the ground potential at the resonant frequency fr2 of the parallel arm resonator P1 and, hence, the peak A3 is suppressed. In other words, the peak A5 illustrated in FIG. 4 is suppressed. Hence, out-of-band attenuation is sufficiently increased and favorable filter characteristics are obtained.

Consequently, in the ladder filter 11 of the second preferred embodiment, the band width of the pass band is further reduced and attenuation outside of the pass band is increased.

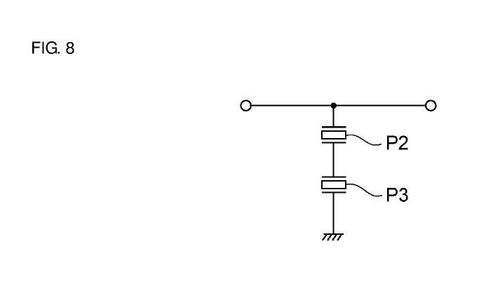

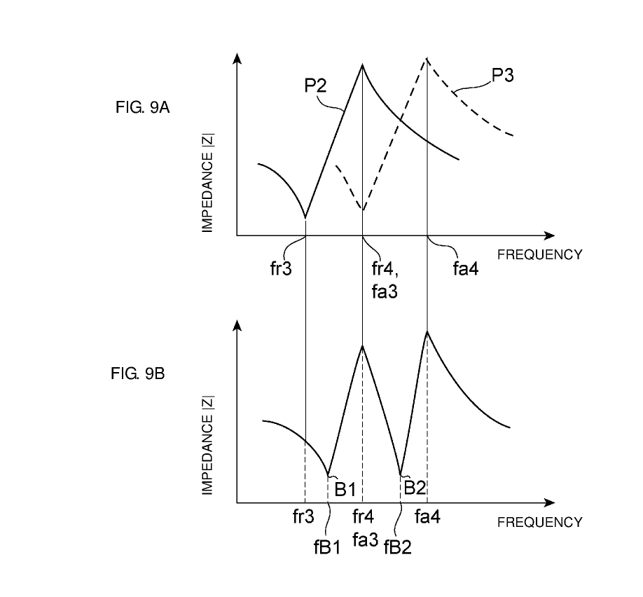

FIG. 8 illustrates a circuit in which the parallel arm resonator P2 as the third parallel arm resonator and the parallel arm resonator P3 as the fourth parallel arm resonator are connected in series with each other. The impedance-frequency characteristics of the third parallel arm resonator P2 and the fourth parallel arm resonator P3 are illustrated in FIG. 9A. The third parallel arm resonator P2 is a parallel arm resonator to provide the original pass band of the ladder filter 1. Hence, a resonant frequency fr3 defines an attenuation pole located in a frequency range below the pass band, and the anti-resonant frequency fa3 is located within the pass band.

On the other hand, a resonant frequency fr4 of the fourth parallel arm resonator P4 is approximately the same as the anti-resonant frequency fa3. In the present preferred embodiment, the parallel arm resonator P3 has a resonant frequency and an anti-resonant frequency similar to those of the series arm resonators S1, S3, S4, and S5, illustrated in FIG. 1. Hence, the anti-resonant frequency fa4 is the same as that of the attenuation pole located in a frequency range above the pass band. On the other hand, the resonant frequency fr4 is located within the pass band. Preferably, the resonant frequency fr4 is the same or substantially the same as the anti-resonant frequency fa3, but is not specifically limited. With this configuration, attenuation within the pass band is sufficiently reduced.

FIG. 9B is a diagram illustrating the composite impedance-frequency characteristics of the circuit illustrated in FIG. 8. When the third parallel arm resonator P2 and the fourth parallel arm resonator P3 are connected in series with each other, two locally minimum points B1 and B2 appear in the frequency characteristics of the composite impedance, as illustrated in FIG. 9B. A frequency fB2 of the locally minimum point B2 is a frequency lower than the anti-resonant frequency fa4. On the other hand, a frequency fB1 of the locally minimum point B1 is a frequency higher than the resonant frequency fr3.

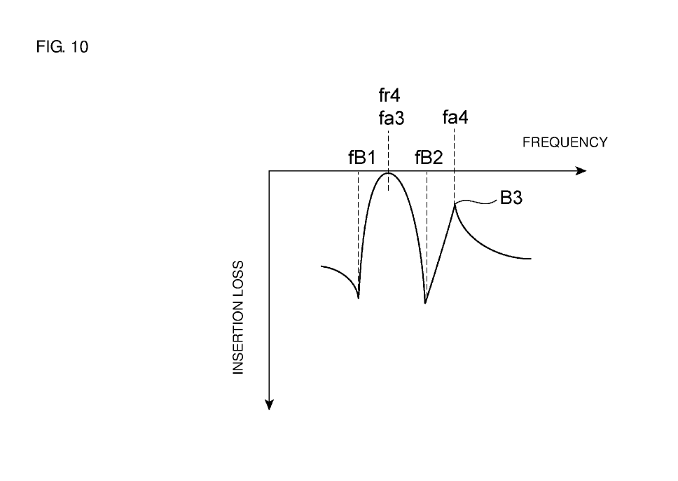

FIG. 10 is a diagram illustrating the attenuation-frequency characteristics of the circuit configuration illustrated in FIG. 8. In the circuit illustrated in FIG. 8, attenuation poles in frequency ranges below and above the pass band are located respectively at the frequencies fB1 and fB2. As a result, compared with the filter characteristics in the case where only the parallel arm resonator P2 is used and the parallel arm resonator P3 is not used, the frequency of the attenuation pole is shifted toward the center frequency independent of whether the frequency of the attenuation pole is located below or above the pass band. Hence, the band width can be reduced. In addition, since the attenuation poles become closer to the center frequency, the steepness of the filter characteristics is sufficiently enhanced. In addition, since the third parallel arm resonator P2 and the fourth parallel arm resonator P3 are connected in series with each other on the parallel arm, applied power is divided. Hence, electric power handling capability is enhanced.

However, as illustrated in FIG. 10, a peak B3 causing small attenuation appears in a frequency range above the pass band.

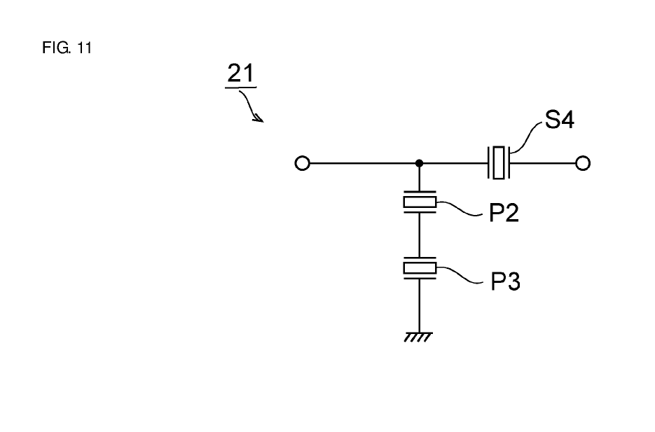

Hence, it is preferable to suppress the peak B3, to obtain favorable filter characteristics. FIG. 11 is a circuit diagram of a ladder filter 21 according to a third preferred embodiment of the present invention, which suppresses such a peak. The ladder filter 21 includes a series arm resonator S4, in addition to the third parallel arm resonator P2 and the fourth parallel arm resonator P3 described above. The resonant frequency and the anti-resonant frequency of the series arm resonator S4 are respectively the same as the resonant frequency and the anti-resonant frequency of the fourth parallel arm resonator P3. The magnitudes |z| of the impedances may be different from each other.

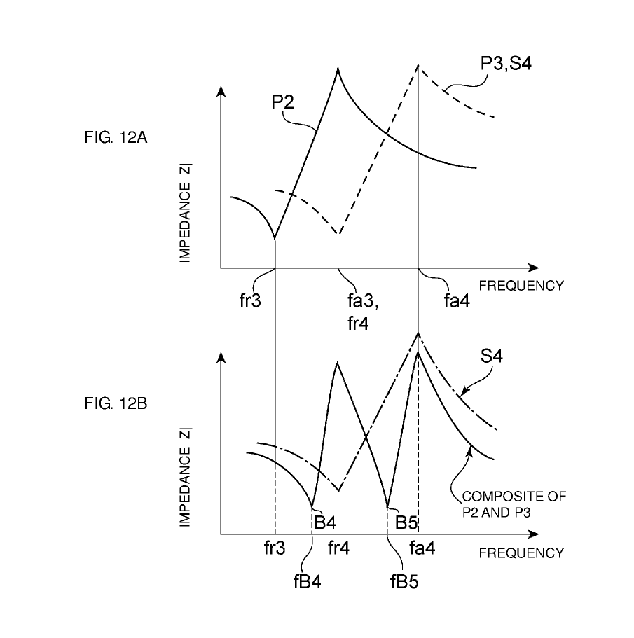

FIG. 12A illustrates the impedance-frequency characteristics of the third parallel arm resonator P2 and the fourth parallel arm resonator P3. The resonant frequency and the anti-resonant frequency of the series arm resonator S4 described above are respectively the same as the resonant frequency and the anti-resonant frequency of the fourth parallel arm resonator P3, as described above. The magnitudes |z| of the impedances may be different from each other.

FIG. 12B is a diagram illustrating the impedance-frequency characteristics between the input and output terminals in the ladder filter 21.

Here, locally minimum points B4 and B5 in the impedance appear. Frequencies fB4 and fB5 of the locally minimum points B4 and B5 are respectively the same or substantially the same as the frequencies fB1 and fB2 illustrated in FIG. 9B.

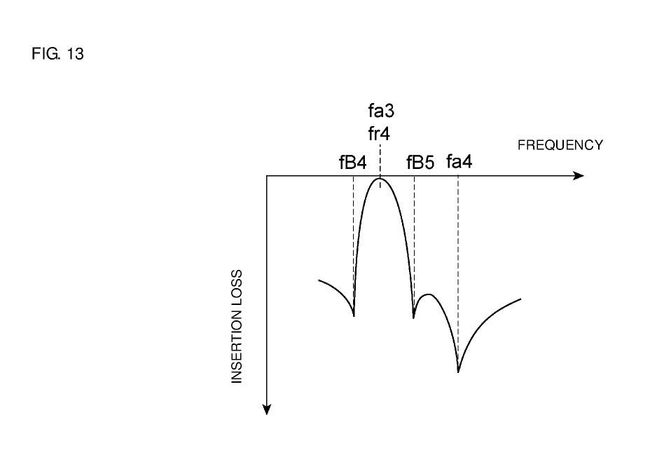

In the ladder filter 21 of the third preferred embodiment, a peak in a frequency range above the pass band is suppressed in the attenuation-frequency characteristics of the ladder filter illustrated in FIG. 13. In other words, the peak B3 illustrated in FIG. 10 is suppressed. This is because attenuation is sufficiently increased at the anti-resonant frequency fa4 of the series arm resonator S4. Hence the out-of-band attenuation is sufficiently increased, and favorable filter characteristics are obtained.

Hence, also in the ladder filter 21 of the third preferred embodiment, the band width of the pass band is reduced and attenuation outside of the pass band is increased. In addition, electric power handling capability is enhanced.

As described above, according to the ladder filters 11 and 21 of the second preferred embodiment and the third preferred embodiment, reduction in the band width and the steepness of the filter characteristics are both realized.

The ladder filter 1 of the first preferred embodiment illustrated in FIG. 1 includes both of the structure of the second preferred embodiment and the structure of the third preferred embodiment. Hence, the band width in the filter characteristics is further reduced and the steepness of the filter characteristics is further enhanced.

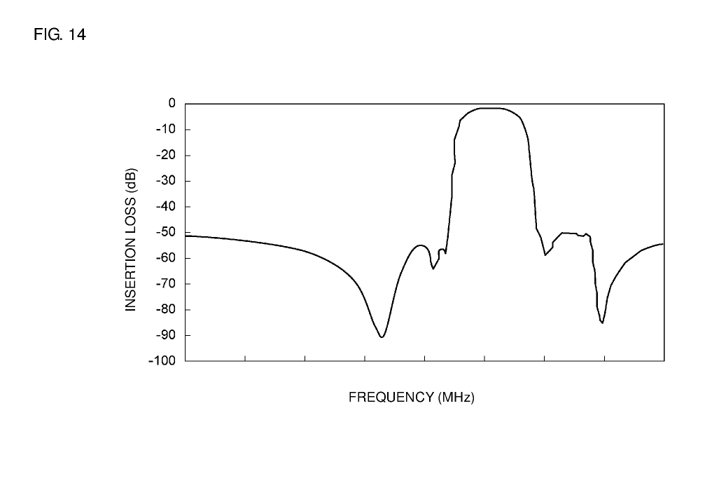

FIG. 14 illustrates the attenuation-frequency characteristics of the ladder filter 1 of the first preferred embodiment. As is clear from FIG. 14, the steepness of the filter characteristics is effectively enhanced. Further, the out-of-band attenuation is sufficiently increased. In other words, peaks at which attenuation is decreased are effectively suppressed in frequency ranges below and above the pass band. Hence, the out-of-band attenuation is increased. Further, electric power handling capability is enhanced.

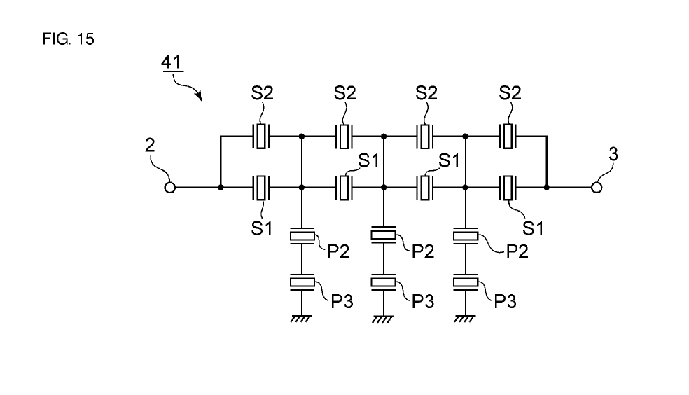

Note that the number of stages and the number of devices of a ladder filter circuit are not specifically limited in the present invention. FIG. 15 to FIG. 17 are circuit diagrams of ladder filters according to fourth to sixth preferred embodiments of the present invention.

As in a ladder filter 41 of a fourth preferred embodiment of the present invention illustrated in FIG. 15, the second series arm resonators S2 may be respectively connected in parallel with the plurality of first series arm resonators S1. Further, on each of the plurality of parallel arms, the third parallel arm resonator P2 and the fourth parallel arm resonator P3 may be connected in series with each other.

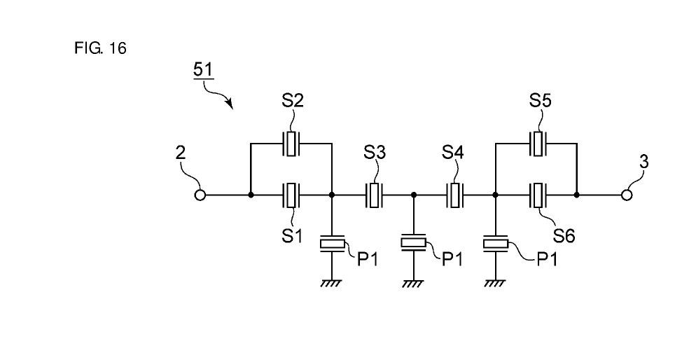

As in a ladder filter 51 of a fifth preferred embodiment illustrated in FIG. 16, a configuration may be provided in which the first series arm resonator S1 and the second series arm resonator S2 are arranged on the series arm, and the third and fourth parallel arm resonators are not provided on the parallel arm. In the ladder filter 51, the parallel arm resonator P1 defining a pass band is provided on each parallel arm.

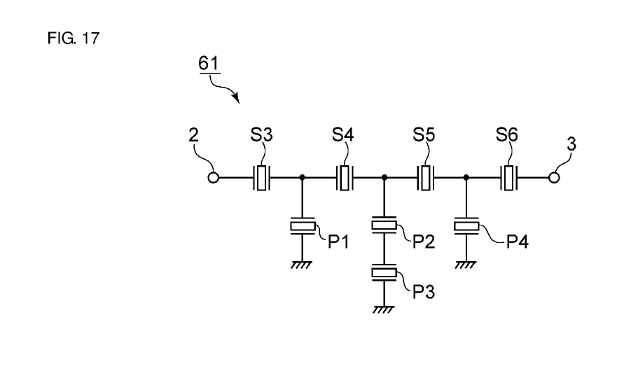

In a ladder filter 61 of a sixth preferred embodiment illustrated in FIG. 17, third and fourth parallel arm resonators P2 and P3 are connected in series with each other, and only ordinary series arm resonators S3 to S6 defining a pass band are provided on the series arm.

As in the fifth and sixth preferred embodiments, only one of the combination of the first and second series arm resonators and the combination of the third and fourth parallel arm resonators may be used.

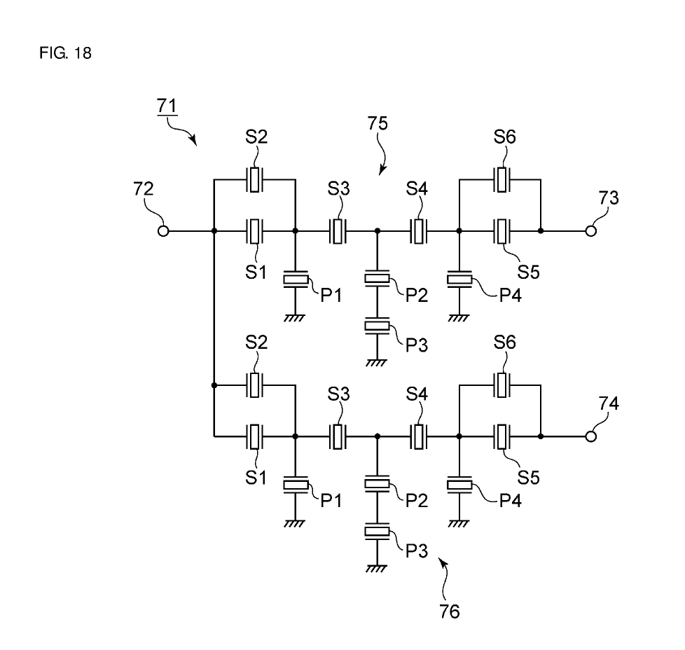

FIG. 18 is a circuit diagram illustrating a duplexer as a seventh preferred embodiment of the present invention. In a duplexer 71, a transmission filter 75 is connected between a common terminal 72 connected to an antenna and a transmission terminal 73. A reception filter 76 is connected between the common terminal 72 and a reception terminal 74. Each of the transmission filter 75 and the reception filter 76 has a circuit configuration similar to that of the ladder filter 1 of the first preferred embodiment.

In the transmission filter 75, the transmission terminal 73 is an input terminal and the common terminal 72 is an output terminal. On the other hand, in the reception filter 76, the common terminal 72 is an input terminal and the reception terminal 74 is an output terminal.

Each of the transmission filter 75 and the reception filter 76 includes the first and second series arm resonators S1 and S2 and the third and fourth parallel arm resonators P2 and P3 described above. Hence, in both of the transmission filter 75 and the reception filter 76, the band width is reduced and the steepness of the filter characteristics is enhanced.

Preferably, as illustrated in FIG. 18, the resonators closest to the common terminal 72 on each of the signal lines of the transmission filter 75 and the reception filter 76 are the first and second series arm resonators S1 and S2. With this configuration, the electric power handling capability is further effectively enhanced.

In the transmission filter 75, it is preferable that the resonators on the signal line closest to the transmission terminal 73, on the power input side, be the first and second series arm resonators S1 and S2. The electric power handling capability is enhanced also by this configuration.

The transmission filter 75 defining a ladder filter allows the electric power handling capability to be enhanced, the band width to be reduced, and the steepness of the filter characteristics to be enhanced, as described above.

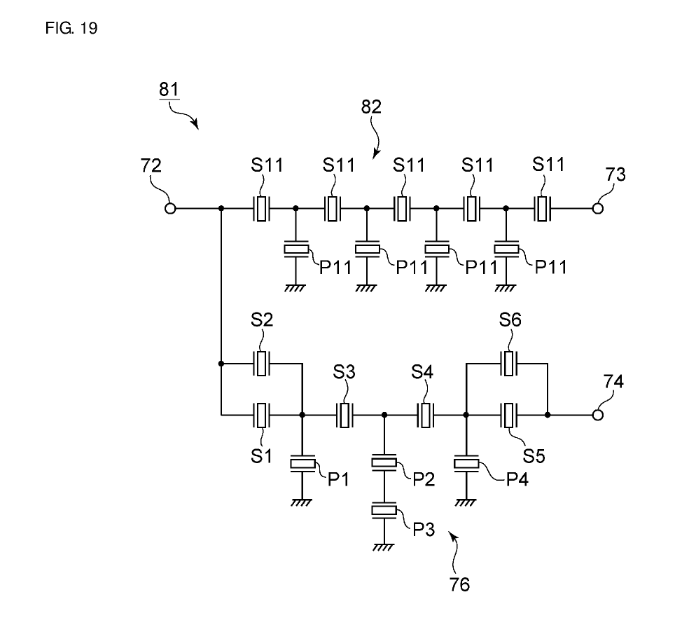

FIG. 19 is a circuit diagram of a duplexer according to an eighth preferred embodiment of the present invention. In a duplexer 81, a transmission filter 82 does not include the second series arm resonator S2. A plurality of series arm resonators S11 defining a pass band are provided. The transmission filter 82 does not include the fourth parallel arm resonator P3 either, and includes a plurality of parallel arm resonators P11 that define the pass band. In other words, all of the series arm resonators and all of the parallel arm resonators are respectively made to be the series arm resonators S11 and the parallel arm resonators P11 defining the pass band of an ordinary ladder filter.

The rest of the configuration of the duplexer 81 is similar to that of the duplexer 71. The characteristic configuration of various preferred embodiments of the present invention may be used only in the reception filter 76, as in the duplexer 81. With this configuration, the band width is reduced and the steepness of the filter characteristics and the electric power handling capability are enhanced, in the reception filter 76.

In various preferred embodiments of the present invention, as in the duplexer 81, in a complex filter in which first ends of a plurality of band pass filters are connected to one another, the configuration of various preferred embodiments of the present invention may be provided only in one of the filters. In other words, it is only required that at least one of the combination of the first and second series arm resonators and the combination of the third and fourth parallel arm resonators of the present invention be provided in at least one band pass filter among a plurality of band pass filters.

Further, although surface acoustic wave resonators are used in the preferred embodiments, the first and second series arm resonators and the third and fourth parallel arm resonators in various preferred embodiments of the present invention are able to be defined by appropriate acoustic resonators including a resonant point and an anti-resonant point. Examples of such acoustic resonators which can be used include a boundary acoustic wave resonator, a BAW resonator using a piezoelectric thin film, and a single-plate or multilayer piezoelectric resonator, not limited to surface acoustic wave resonators.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A ladder filter including a pass band, the ladder filter comprising:
an input terminal;
an output terminal;
at least one series arm resonator arranged on a series arm connecting the input terminal and the output terminal to each other; and
at least one parallel arm resonator provided on a parallel arm connected between the series arm and a ground potential; wherein
the at least one series arm resonator and the at least one parallel arm resonator are resonators each including a resonant point and an anti-resonant point;
the at least one series arm resonator includes a first series arm resonator and a second series arm resonator connected in parallel with each other; and
for a resonant frequency fr1 and an anti-resonant frequency fa1 of the first series arm resonator, and for a resonant frequency fr2 and an anti-resonant frequency fa2 of the second series arm resonator, a relation is satisfied when fr1>fr2 and fa1>fa2, the relation being a resonant frequency difference Δfr=|fr1−fr2|>|fa2−fr1|.

2. The ladder filter according to claim 1, wherein the resonant frequency fr1 of the first series arm resonator and the anti-resonant frequency fa2 of the second series arm resonator are located within the pass band.

3. The ladder filter according to claim 1, wherein the at least one parallel arm resonator includes a first parallel arm resonator defining the pass band.

4. The ladder filter according to claim 1, wherein the at least one parallel arm resonator includes a second parallel arm resonator that has a same or substantially a same resonant frequency and a same or substantially a same anti-resonant frequency as a resonant frequency and an anti-resonant frequency of the first series arm resonator respectively.

5. The ladder filter according to claim 1, wherein a third series arm resonator is connected in parallel with the first series arm resonator and the second series arm resonator.

6. The ladder filter according to claim 1, wherein a fourth series arm resonator is provided on the series arm in series with the first and second series arm resonators.

7. A ladder filter including a pass band, the ladder filter comprising:
an input terminal;
an output terminal;
at least one series arm resonator arranged on a series arm connecting the input terminal and the output terminal to each other; and
at least one parallel arm resonator provided on a parallel arm connected between the series arm and a ground potential; wherein
the at least one series arm resonator and the at least one parallel arm resonator are resonators each including a resonant point and an anti-resonant point;
the at least one parallel arm resonator includes a third parallel arm resonator and a fourth parallel arm resonator connected in series with each other on the parallel arm; and
for a resonant frequency fr3 and an anti-resonant frequency fa3 of the third parallel arm resonator and for a resonant frequency fr4 and an anti-resonant frequency fa4 of the fourth parallel arm resonator, a relation is satisfied when fr3<fr4 and fa3<fa4, the relation being a resonant frequency difference Δfr=|fr3−fr4|>|fr4−fa3|.

8. The ladder filter according to claim 7, wherein the anti-resonant frequency fa3 of the third parallel arm resonator and the resonant frequency fr4 of the fourth parallel arm resonator are located within the pass band.

9. The ladder filter according to claim 7, wherein the at least one series arm resonator includes a fifth series arm resonator defining the pass band.

10. The ladder filter according to claim 7, wherein the at least one series arm resonator includes a sixth series arm resonator that has a same or substantially a same resonant frequency and a same or substantially a same anti-resonant frequency as a resonant frequency and an anti-resonant frequency of the third parallel arm resonator respectively.

11. The ladder filter according to claim 7, wherein a fifth parallel arm resonator is connected in series with the third parallel arm resonator and the fourth parallel arm resonator.

12. The ladder filter according to claim 7, wherein a different parallel arm different from the parallel arm on which the third and fourth parallel arm resonators are provided is provided, and a sixth parallel arm resonator is provided on the different parallel arm.

13. The ladder filter according to claim 1, wherein respective fractional band widths of all the resonators are equal or substantially equal.

14. The ladder filter according to claim 1, wherein all the resonators are provided on a same piezoelectric substrate.

15. The ladder filter according to claim 1, wherein the at least one series arm resonator and the at least one parallel arm resonator are each a surface acoustic wave resonator.

16. The ladder filter according to claim 7, wherein respective fractional band widths of all the resonators are equal or substantially equal.

17. The ladder filter according to claim 7, wherein all the resonators are provided on a same piezoelectric substrate.

18. The ladder filter according to claim 7, wherein the at least one series arm resonator and the at least one parallel arm resonator are each a surface acoustic wave resonator.
